(19) United States
(12) Patent Application Publication
(10) Pub. No.: US 2010/0019222 A1
(43) Pub. Date: Jan. 28, 2010

(54) LOW-TEMPERATURE LED CHIP METAL BONDING LAYER

(75) Inventors: Liang-Jyi Yan, Xindian City (TW); Chih-Sung Chang, Hsinchu City (TW)

Correspondence Address: APEX JURIS, PLLC, 12733 LAKE CITY WAY NORTHEAST, SEATTLE, WA, 98125, US

(73) Assignee: HIGH POWER OPTO.INC., Taichung County (TW)

(21) Appl. No.: 12/180,412

(22) Filed: Jul. 25, 2008

(51) Int. Cl. H01L 33/00

(52) U.S. Cl. 257/13; 257/E33.032

(57) ABSTRACT

The present invention discloses a low-temperature light-emitting-diode chip metal bonding layer, which comprises: a first metal layer formed on the joint surface of an LED epitaxial layer and containing an ITO layer, a silver layer, a titanium layer, a platinum layer and a gold layer sequentially arranged from the LED epitaxial layer; and a second metal layer formed on the joint surface of the substrate and containing a titanium layer, a gold layer and an indium layer sequentially arranged from the substrate. Because of the low melting point of the indium layer, the bonding process of the substrate and the LED chip epitaxial layer can be undertaken at a relatively low temperature. Therefore, the present invention can prevent the film structures from being damaged by high temperature and can raise the yield of metal bonding LED chips.

### FIELD OF THE INVENTION

The present invention relates to a low-temperature LED chip metal bonding layer, particularly to a metal bonding layer bonding an LED epitaxial layer to a substrate in a metal bonding process of an LED chip.

### BACKGROUND OF THE INVENTION

LED (Light Emitting Diode) is a luminescent element, wherein current is applied to a III-V group compound semiconductor, and energy is released in form of light in the recombination of electrons and holes. LED does not burn as an incandescent lamp. Further, LED has a small volume, long service life, low driving voltage, high response speed and superior vibration resistance. Thus, LED can satisfy the demand for lightweight and compactness and has become a very popular product in daily living. LED has greatly advanced in the performance and efficiency thereof and has been extensively used in daily living. Via different compound semiconductors and structures, LED may emit red, orange, yellow, green blue, violet, infrared, or ultraviolet light. Now, LED has been widely used in outdoor signboards, brake lights, traffic lights and display devices.

The main component of LED is the LED epitaxial layer (also called the LED chip), which is a luminescent semiconductor material. The LED epitaxial layer may be formed via depositing four elements—aluminum, gallium, indium and phosphor. Alternatively, the LED epitaxial layer may be formed of another semiconductor material, such as GaP (gallium phosphide), GaAlAs (gallium aluminum arsenide), GaAs (gallium arsenide), or GaN (gallium nitride). LED has a PN structure and a unidirectional conductivity.

Among LED structures, there is a metal bonding chip, wherein a metal bonding layer is used to bond the LED epitaxial layer to the substrate. The metal bonding layer also functions as a reflecting plane, which reflects photons lest photons be absorbed by the substrate, whereby the external quantum efficiency is promoted.

The conventional metal bonding layer is an AuSn (gold tin) film or an AuNi (gold nickel) film, which is formed on the joint surface of the substrate and bonded to a silver-containing conductive layer (also used as a reflecting plane) formed on the joint surface of the LED epitaxial layer. However, the AuSn or AuNi film has a high melting point. Thus, the bonding process of the substrate and LED epitaxial layer needs a temperature of 300-900° C. and a pressure of 500-5000 psi. A bonding temperature as high as 300-900° C. will damage the silver or aluminum conductive layer and the reflecting plane.

### SUMMARY OF THE INVENTION

The primary objective of the present invention is to reduce the bonding temperature of the substrate and the epitaxial layer via varying the composition of the metal bonding layer, whereby the conventional problem that a high bonding temperature damages the metal film is solved, and the yield of LED is promoted.

To solve the above-mentioned problem and achieve the above-mentioned objective, the present invention proposes a low-temperature LED chip metal bonding layer, which is used to bond an LED epitaxial layer to a substrate and comprises: a first metal layer formed on the joint surface of the LED epitaxial layer, wherein the outmost layer of the first metal layer is a gold layer; and a second metal layer formed on the joint surface of the substrate, wherein the outmost layer of the second metal layer is an indium layer. As the indium layer has a low melting point, the LED chip metal bonding layer of the present invention can be formed at a relatively low temperature.

The present invention is characterized in that the indium layer of the second metal layer has a low melting point. Because of the low-melting point indium layer, the bonding process of the substrate and the LED epitaxial layer can be undertaken at a temperature of 100-300° C., which is much lower than the conventional bonding temperature of 300-900° C. Thereby, the present invention can simplify the fabrication process and raise the yield of the metal bonding LED chips.

### BRIEF DESCRIPTION OF THE DRAWINGS

FIG. 1 is a diagram schematically showing the structure of an LED epitaxial layer using a low-temperature metal bonding layer according to a preferred embodiment of the present invention.

FIG. 2 is a diagram schematically showing the structure of a substrate using a low-temperature metal bonding layer according to a preferred embodiment of the present invention.

FIG. 3 is a diagram schematically showing the structure of LED using a low-temperature metal bonding layer according to a preferred embodiment of the present invention.

### DETAILED DESCRIPTION OF THE PREFERRED EMBODIMENTS

Below, the technical contents of the present invention will be described in detail with embodiments. However, it should be understood that the embodiments are only to exemplify the present invention but not to limit the scope of the present invention.

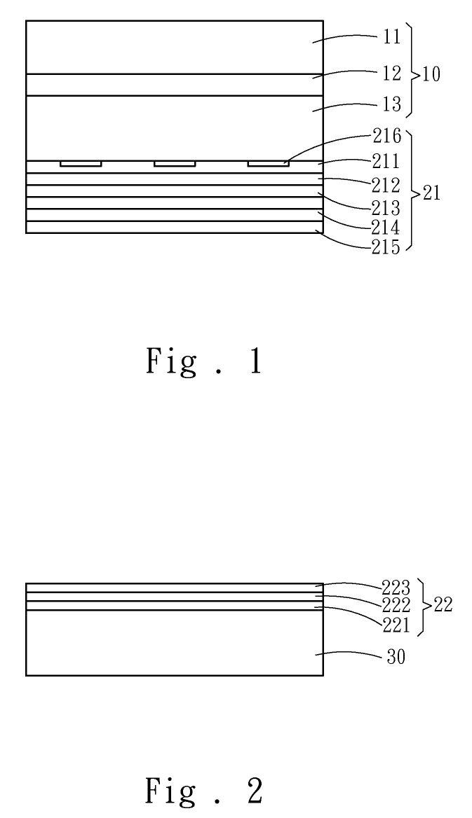

Refer to FIG. 1. In FIG. 1, an LED epitaxial layer 10 at least comprises: an electron supply layer 11, a hole supply layer 13 and an active layer 12. The LED epitaxial layer 10 may be fabricated with a MOCVD (Metal Organic Chemical Vapor Deposition) method, an LPE (Liquid Phase Epitaxy) method, or a MBE (Molecular Beam Epitaxy) method. The active layer 12 adopts a MQW (Multiple Quantum Well) structure as the light emitting zone, wherein the MQW structure is formed of an AlInGaN-containing periodic structure. The electron supply layer 11 is made of an N-type gallium nitride (GaN) or an N-type indium gallium nitride (InGaN). The hole supply layer 13 is made of a P-type gallium nitride (GaN) or a P-type indium gallium nitride (InGaN). Alternatively, the active layer 12 adopts a MQW structure formed of an AlInGaP-containing periodic structure; the electron supply layer 11 is made of an N-type aluminum indium gallium phosphide (AlInGaP), and the hole supply layer 13 is made of a P-type aluminum indium gallium phosphide (AlInGaP).

A first metal layer 21 is formed on the surface of the hole supply layer 13. The first metal layer 21 contains an ITO (Indium Tin Oxide) layer 211, a silver layer 212, a titanium layer 213, a platinum layer 214 and a gold layer 215 sequentially arranged from the hole supply layer 13 of the LED epitaxial layer 10. Further, an AuBe (gold beryllium) alloy pad 216 is formed between the ITO layer 211 and the LED epitaxial layer 10 (the hole supply layer 13) to increase the electric conductivity therebetween.

Refer to FIG. 2. A second metal layer 22 is formed on the surface of a substrate 30. The substrate 30 has a high thermal conductivity and is made of a material selected from the group consisting of silicon, aluminum, copper, silver, silicon carbide (SiC), diamond, graphite, molybdenum, and aluminum nitride. The second metal layer 22 contains a titanium layer 221, a gold layer 222 and an indium layer 223 sequentially arranged from the substrate 30, and the indium layer 223 has a thickness of 0.5-4 μm.

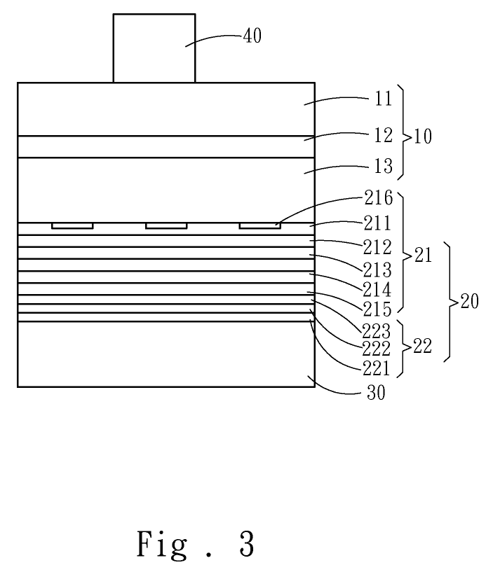

Refer to FIG. 3. The first metal layer 21 on the LED epitaxial layer 10 is bonded to the second metal layer 22 on the substrate 30, and the first and second metal layers 21 and 22 thus form a metal bonding layer 20, wherein the indium layer 223 of the second metal layer 22 is bonded to the gold layer 215 of the first metal layer 21. As the indium layer 223 of the second metal layer 22 of the present invention has a low melting point, the bonding process of the substrate 30 and the LED epitaxial layer 10 can be undertaken at a bonding temperature of 100-300° C. and a bonding pressure of 500-5000 psi.

Compared with the conventional high bonding temperature of 300-900° C., the metal bonding layer 20 of the present invention only needs a bonding temperature of as low as 100-300° C. The low bonding temperature of the metal bonding layer 20 of the present invention can simplify the fabrication process and raise the yield of the metal bonding LED chips without decreasing the electrical connection effect thereof.

After the LED epitaxial layer 10 is bonded to the substrate 30 via the metal bonding layer 20, an ohmic contact layer 40 is formed on the electron supply layer 11 of the LED epitaxial layer 10. Thus is completed a metal bonding LED chip.

What is claimed is:

1. A low-temperature light-emitting-diode chip metal bonding layer, which is used to bond an LED (Light Emitting Diode) epitaxial layer to a substrate and comprises:
a first metal layer formed on the joint surface of said LED epitaxial layer, wherein the outmost layer of said first metal layer is a gold layer; and
a second metal layer formed on the joint surface of said substrate, wherein the outmost layer of said second metal layer is an indium layer.

2. The low-temperature light-emitting-diode chip metal bonding layer according to claim 1, wherein said first metal layer contains an ITO (Indium Tin Oxide) layer, a silver layer, a titanium layer, a platinum layer and a gold layer sequentially arranged from said LED epitaxial layer; said second metal layer contains a titanium layer, a gold layer and an indium layer sequentially arranged from said substrate.

3. The low-temperature light-emitting-diode chip metal bonding layer according to claim 2, wherein an AuBe (gold beryllium) alloy pad is formed between said ITO layer and said LED epitaxial layer.

4. The low-temperature light-emitting-diode chip metal bonding layer according to claim 1, wherein said indium layer of said second metal layer has a thickness of 0.5-4 μm.

5. The low-temperature light-emitting-diode chip metal bonding layer according to claim 1, wherein said substrate is made of a material selected from a group consisting of silicon, aluminum, copper, silver, silicon carbide (SiC), diamond, graphite, molybdenum, and aluminum nitride.

6. The low-temperature light-emitting-diode chip metal bonding layer according to claim 1, wherein said LED epitaxial layer at least comprises: an electron supply layer, a hole supply layer and an active layer.

7. The low-temperature light-emitting-diode chip metal bonding layer according to claim 6, wherein said active layer contains multiple layers of quantum wells formed of a periodic aluminum indium gallium nitride (AlInGaN) structure; said electron supply layer is made of an N-type gallium nitride (GaN) or an N-type indium gallium nitride (InGaN); said hole supply layer is made of a P-type gallium nitride (GaN) or a P-type indium gallium nitride (InGaN).

8. The low-temperature light-emitting-diode chip metal bonding layer according to claim 6, wherein said active layer contains multiple layers of quantum wells formed of a periodic aluminum indium gallium phosphide (AlInGaP) structure; said electron supply layer is made of an N-type aluminum indium gallium phosphide (AlInGaP); said hole supply layer is made of a P-type aluminum indium gallium phosphide (AlInGaP).
